(19) United States
(12) Patent Application Publication
(10) Pub. No.: US 2026/0280465 A1
(43) Pub. Date: Sep. 17, 2026

(54) MOTOR DRIVE SYSTEM, LITHOGRAPHY APPARATUS, AND METHOD FOR MANUFACTURING ARTICLE

(71) Applicant: CANON KABUSHIKI KAISHA, Tokyo (JP)

(72) Inventor: SHINJI OHISHI, Tochigi (JP)

(21) Appl. No.: 19/544,832

(22) Filed: Feb. 19, 2026

(30) Foreign Application Priority Data
Mar. 14, 2025 (JP) 2025-041445

(51) Int. Cl. H02P 27/06; G03F 7/00

(52) U.S. Cl. CPC H02P 27/06; G03F 7/70725

(57) ABSTRACT

A motor drive system includes a first driver that receives power from a first power supply and supply power to a first motor, a second driver that receives power from a second power supply and supply power to a second motor, and a setting unit that sets a value of a current supplied from the second power supply to the second driver based on information about driving of the first motor and the second motor.

### BACKGROUND

### Field of the Technology

The present disclosure relates to a motor drive system, a lithography apparatus and a method for manufacturing an article.

### Description of the Related Art

In a process for manufacturing a semiconductor device, a liquid crystal display device, or the like, there are cases in which a motor drive system that simultaneously drives a first motor and a second motor is used (Japanese Patent Laid-Open No. 2015-79823).

In a motor drive system that simultaneously drives two motors, a total current value, which is a sum of the current value output from a first power supply that supplies power to the first motor and the current value output from a second power supply that supplies power to the second motor, sometimes increases, thereby making the size of the motor drive system large.

### SUMMARY

The present disclosure is directed to providing a compact motor drive system.

According to an aspect of the present disclosure, a motor drive system includes a first driver configured to receive power from a first power supply and supply power to a first motor, a second driver configured to receive power from a second power supply and supply power to a second motor, and a setting unit configured to set a value of a current supplied from the second power supply to the second driver based on information about driving of the first motor and the second motor.

Features of the present disclosure will become apparent from the following description of embodiments with reference to the attached drawings. The following description of embodiments is described by way of example.

### BRIEF DESCRIPTION OF THE DRAWINGS

FIG. 1 schematically illustrates a configuration of a lithography apparatus according to a first embodiment.

FIG. 2 schematically illustrates a motor drive system according to the first embodiment.

FIG. 3 illustrates an operation example of a conventional motor drive system.

FIG. 4 illustrates a detailed configuration of a power supply.

FIG. 5 is a flowchart illustrating a process for switching a current value according to the first embodiment.

FIG. 6 illustrates an operation example of the motor drive system when one motor is driven according to the first embodiment.

FIG. 7 is an operation example of the motor drive system when two motors simultaneously receive power according to the first embodiment.

FIG. 8 is a flowchart illustrating a method for manufacturing an article according to a second embodiment.

### DESCRIPTION OF THE EMBODIMENTS

Hereinafter, embodiments of the present disclosure will be described with reference to the drawings. The following embodiments are not seen to be limiting. While a plurality of features are described in the embodiments, all of the plurality of features are not necessarily essential to the disclosure, and the embodiments may be combined as desired. In the drawings, the same or similar components are denoted by the same reference numerals, and redundant description thereof will be omitted.

In the present specification and the drawings, directions are basically represented by an XYZ coordinate system in which the axes are perpendicular to each other. In the XYZ coordinate system, the vertical direction is the Z-axis direction, and a horizontal plane perpendicular to the vertical direction is the XY plane. When an XYZ coordinate system is illustrated in a drawing, this coordinate system in the drawing is prioritized.

Hereinafter, a specific configuration will be described in each embodiment.

### First Embodiment

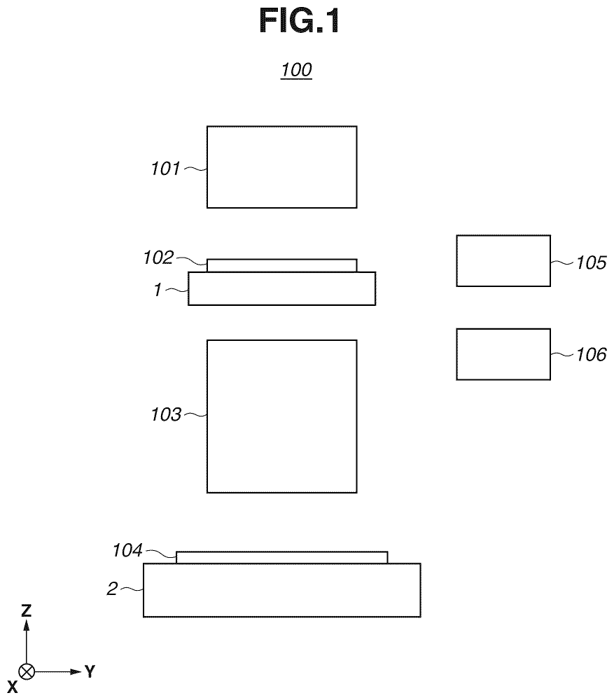

FIG. 1 schematically illustrates a configuration of a lithography apparatus 100 according to a first embodiment. In the present embodiment, the lithography apparatus 100 is a projection exposure apparatus that projects a pattern of an original plate (mask, reticle) onto a substrate via a projection optical system by using a step-and-repeat method or a step-and-scan method.

The lithography apparatus 100 includes an illumination optical system 101 that emits light, a reticle stage 1 that secures a reticle 102, a projection optical system 103, a substrate stage 2 that is movable while securing a substrate 104, a control unit 105, and a storage unit 106. The reticle 102 is, for example, an original plate in which a pattern (e.g., a circuit pattern) to be transferred is formed on a surface of quartz glass with chromium. The substrate 104 is, for example, single-crystal silicon, and photosensitive material (photoresist) is applied on its surface. The control unit 105 controls each component of the lithography apparatus 100. The storage unit 106 stores, for example, information (drive profile) about the driving of the reticle stage 1 and the substrate stage 2. The drive profile indicates information about, for example, driving (acceleration movement (drive), deceleration movement (drive), and constant-velocity movement (drive)) of each stage (motor) with respect to time. The drive profile may also include information about a current value needed to drive a corresponding motor.

The control unit 105 includes a processing unit, a bus, a read-only memory (ROM), a random-access memory (RAM), and a storage device. Each component functions in accordance with a program. The processing unit is a processing device that performs arithmetic operations for control in accordance with a program, and controls each component connected to the bus. This processing unit can be configured by a central processing unit (CPU), a programmable logic device (PLD) such as a field-programmable gate array (FPGA), an application-specific integrated circuit (ASIC), a computer in which programs are incorporated, or a combination of all or some of these components. The ROM is a memory dedicated to data reading, and stores programs and data. The RAM is a memory for reading and writing data, and is used for storing the programs and data. The RAM is used for temporarily storing data such as the results of arithmetic operations of the CPU. The storage device is also used for storing the programs and data. The storage device is also used as a temporary storage area for programs of an operating system (OS) of the control unit 105 and data. While the storage device is slower in data input and output than the RAM, the storage device can store a large amount of data. It is desirable that the storage device is a non-volatile storage device that can store data as permanent data such that the stored data can be referred to for a long time. The storage device is configured by a magnetic storage device (a hard disk drive (HDD)). The storage device may also be a device that loads an external medium, such as a compact disc (CD), a digital versatile disc (DVD), or a memory card, and reads and writes data.

The control unit 105 and the storage unit 106 may be integrated with the other components of the lithography apparatus 100 (in a shared housing), or may be configured separately (in a separate housing), separated from the other components of the lithography apparatus 100.

In the lithography apparatus 100, exposure light from a light source (not illustrated) illuminates the reticle 102 secured by the reticle stage 1 via the illumination optical system 101. The light transmitted through the reticle 102 is projected onto the substrate 104 via the projection optical system 103. The light from the pattern formed on the reticle 102 forms an image on the surface of the substrate 104, and a shot region of the substrate 104 (the photosensitive material on the substrate 104) is exposed by the pattern image. The lithography apparatus 100 exposes the shot region on the substrate 104 in this manner, and exposes each of a plurality of shot regions in a similar manner. The positions of the reticle stage 1 and the substrate stage 2 are measured by a measuring device (not illustrated), and the stages 1 and 2 are controlled to move to desired positions based on the measurement results of the measuring device.

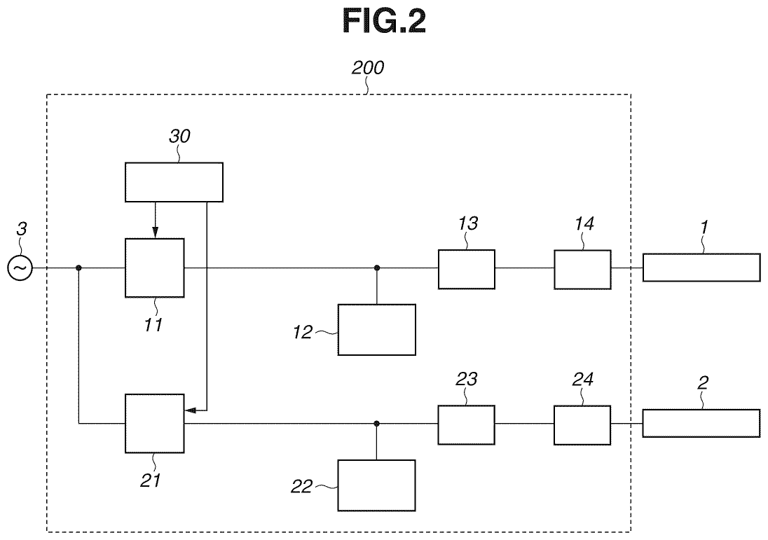

FIG. 2 schematically illustrates a motor drive system 200 according to the present embodiment. The motor drive system 200 includes a drive system for driving the reticle stage 1 and a drive system for driving the substrate stage 2. The drive system for driving the reticle stage 1 includes a first power supply (a first constant voltage power supply) 11, a first capacitor 12, a first driver 13, and a first motor 14. The drive system for driving the substrate stage 2 includes a second power supply (a second constant voltage power supply) 21, a second capacitor 22, a second driver 23, and a second motor 24. The first power supply 11 and the second power supply 21 receive power from a source power supply (a utility power supply) 3, which is a power supply on the facility (equipment) side. That is, the first power supply 11 and the second power supply 21 receive power from the same power supply. The first driver 13 receives power from the first power supply 11 and the first capacitor 12, and supplies power to the first motor 14. The first motor 14 is a motor for driving the reticle stage 1.

The second driver 23 receives power from the second power supply 21 and the second capacitor 22, and supplies power to the second motor 24. The second motor 24 is a motor for driving the substrate stage 2.

In the motor drive system 200, there are cases in which the first motor 14 and the second motor 24 are simultaneously driven. For example, when the lithography apparatus 100 uses the step-and-scan method, the reticle stage 1 and the substrate stage 2 move in opposite directions in synchronization with each other. Such movement includes acceleration movement, deceleration movement, and constant-velocity movement, where the movement is controlled based on the drive profile. When the motor drive system 200 simultaneously drives two or more motors as described above, the total current value (the total value), which is a sum of the current value output from the first power supply 11 that supplies power to the first motor 14 and the current value output from the second power supply 21 that supplies power to the second motor 24, can become high. Specifically, when the time period in which the first motor 14 accelerates and the time period in which the second motor 24 accelerates overlap each other, the total current value increases in the overlapping time period.

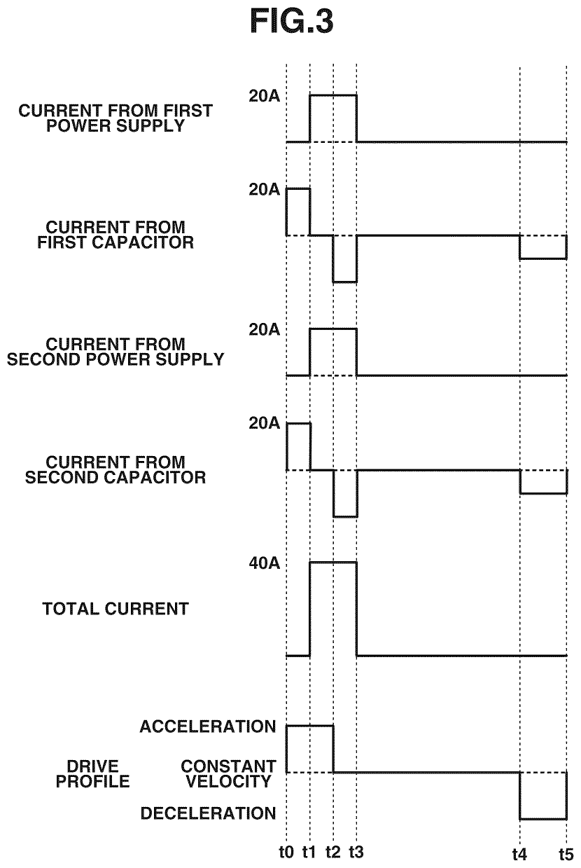

FIG. 3 illustrates an operation example of a conventional motor drive system. In the conventional motor drive system, the output current values of the first power supply and the second power supply are fixed. In the example in FIG. 3, the current values of the first power supply and the second power supply are fixed at 20 (A). The time period from time t0 to time t2 in FIG. 3 is an acceleration period in which the reticle stage 1 and the substrate stage 2 accelerate. The time period from time t2 to time t4 is a constant-velocity period in which the reticle stage 1 and the substrate stage 2 move at a constant velocity. The time period from time t4 to time t5 is a deceleration period in which the reticle stage 1 and the substrate stage 2 decelerate.

In the acceleration period from time t0 to time t1, each of the first capacitor and the second capacitor, which have higher responsiveness than the power supplies, supplies a current of 20 (A) to its corresponding driver. As a result, the first motor and the second motor are driven. In the time period from time t1 to time t2, the capacitors have already supplied all the power stored therein, and thus each of the first power supply and the second power supply supplies a current of 20 (A) to its corresponding driver. As a result, the first motor and the second motor are driven.

In the constant-velocity period from time t2 to time t3, no power needs to be supplied to drive the reticle stage 1 and the substrate stage 2. However, power needs to be supplied to charge the first capacitor and the second capacitor. Thus, the first power supply supplies power to the first capacitor, and the second power supply supplies power to the second capacitor. In the constant-velocity period from time t3 to time t4, the charging of the capacitors is already completed, and thus no power is supplied from the power supplies.

In the deceleration period from time t4 to time t5, the first motor and the second motor decelerate. Thus, a regenerative current returns to each of the first capacitor and the second capacitor, and the first capacitor and the second capacitor are consequently charged.

By performing such operations, the total current value of the first power supply and the second power supply becomes as high as 40 (A). This increases the peak value of the current output from the source power supply, which supplies power to the first power supply and the second power supply. Thus, a breaker having a capacity corresponding to such a high current value needs to be provided. Because thick cables need to be used to supply electricity having a high current value, the size of the motor drive system is increased.

The motor drive system 200 according to the present embodiment also includes a setting unit 30 that sets a current value of at least one of the first power supply 11 or the second power supply 21 based on information (drive profile) about the driving of the first motor 14 and the second motor 24. By setting an appropriate current value of the individual power supply by using the setting unit 30, the peak value of the current output from the source power supply can be reduced.

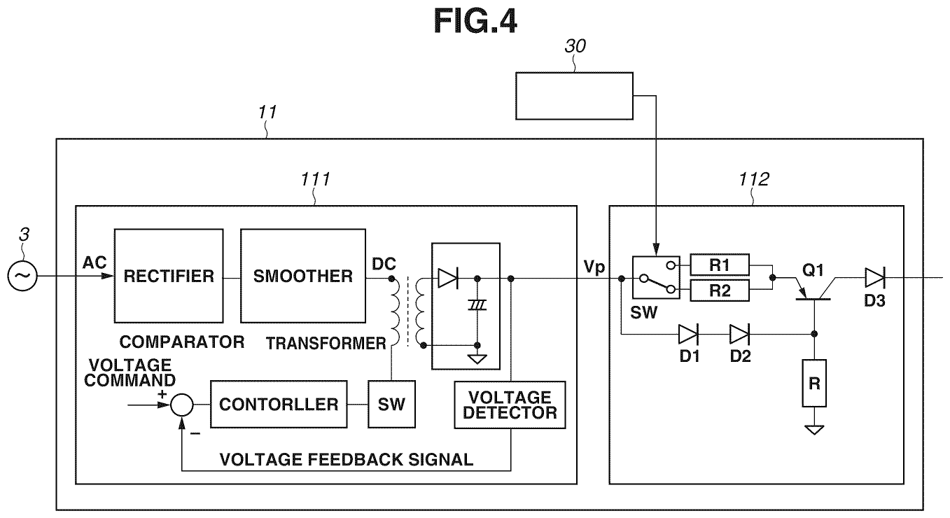

FIG. 4 illustrates a detailed configuration of a power supply. Specifically, FIG. 4 illustrates a detailed configuration of the first power supply 11. The second power supply 21 has the same configuration as that of the first power supply 11. FIG. 4 is an example of a circuit according to the present embodiment. The circuit is not limited to the example in FIG. 4, and may be any circuit that varies the current value of the power supply. The first power supply 11 includes a voltage control unit 111 and a current switching unit 112. The voltage control unit 111 includes a circuit called a flyback converter. The flyback converter is a converter that converts input of an alternating current (AC) from the source power supply 3 into a direct current (DC).

A specific operation of the voltage control unit 111 will now be described. The AC current received from the source power supply 3 is rectified and smoothed to generate a DC voltage, and a comparator compares a voltage feedback signal from a voltage output Vp with a voltage command. A controller amplifies an error signal, and a switching element (SW) controls switching of the DC voltage to output a predetermined voltage output Vp. When the switch is set to ON, the current flows through the primary winding of a transformer, and energy is accumulated by a generated magnetic flux. The polarity of the transformer is opposite to the orientation of the diode, and therefore, no induced current flows through the secondary winding. When the switch is set to OFF, the energy stored in the core is released, and the current flows through the diode. In this way, the voltage is controlled to be the predetermined voltage output Vp.

The current switching unit 112 is a circuit including a PNP transistor Q1, diodes (D1, D2, and D3), resistors (R, R1, and R2), and a switch (SW). The diode D3 is provided to prevent the current from flowing from the load side (motor side) into the first power supply 11. The diode D2 connected to the base of the PNP transistor Q1 is provided for compensating a base-emitter voltage (Vbe). A forward voltage drop (Vd) of the diode D1 varies depending on the temperature and the current flowing through the diode. In this example, the forward voltage drop (Vd) of the diode D1 is assumed to be 0.6 (V). The voltage across the diode D1 does not exceed 0.6 (V), which is the forward voltage drop. The maximum current flowing through the PNP transistor Q1 is therefore limited to the value (current value) obtained by dividing the forward voltage drop Vd by R1 or R2. The switch (SW) selectively connects to the resistor R1 or the resistor R2, and switches the resistor to be connected based on the setting of the setting unit 30.

In the example in FIG. 4, the resistor R1=0.03 (Ω) and the resistor R2=0.06 (Ω). When the resistor R1 is selected and connected, the current value is 20 (A), which is the value obtained by dividing 0.6 (V) by the resistance value 0.03 (Ω). When the resistor R2 is selected and connected, the current value becomes 10 (A), which is the value obtained by dividing 0.6 (V) by the resistance value 0.06 (Ω).

As described above, the current value of the individual power supply can be switched by switching the corresponding resistor to be connected based on a signal based on the setting of the setting unit 30.

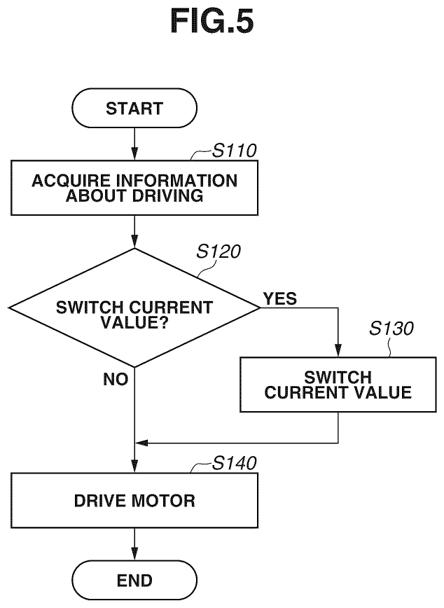

FIG. 5 is a flowchart illustrating a process for switching a current value according to the present embodiment.

First, in step S110, the setting unit 30 acquires information about the driving of the first motor 14 and the second motor 24 from the storage unit 106 or the like. Next, in step S120, the setting unit 30 determines whether to switch the current value of at least one of the first power supply 11 and the second power supply 21 based on the acquired information about the driving. “Switching (setting) the current value of the power supply” is synonymous with “switching (setting) the value of a current supplied from a power supply to a corresponding driver or capacitor”. In step S120, for example, when the first motor 14 and the second motor 24 simultaneously receive power, that is, when the total current value of the first power supply 11 and the second power supply 21 is higher than or equal to a predetermined value (more than or equal to a threshold), the setting unit 30 determines that the current value of at least one power supply is to be switched. When one of the first motor 14 and the second motor 24 is driven, that is, when the total current value of the first power supply 11 and the second power supply 21 is less than the predetermined value, the setting unit 30 determines that the current value of the corresponding power supply is not to be switched.

If the setting unit 30 determines that the current value is to be switched (YES in step S120), the process proceeds to step S130. In step S130, the setting unit 30 switches the current value of at least one of the first power supply 11 and the second power supply 21. In step S140, the motor is driven based on the information about the driving. The switching of the current value in step S130 is performed by, for example, switching the resistance value to be connected as describe above. If the setting unit 30 determines that the current value is not to be switched (NO in step S120), the process proceeds to step S140 without switching the current value.

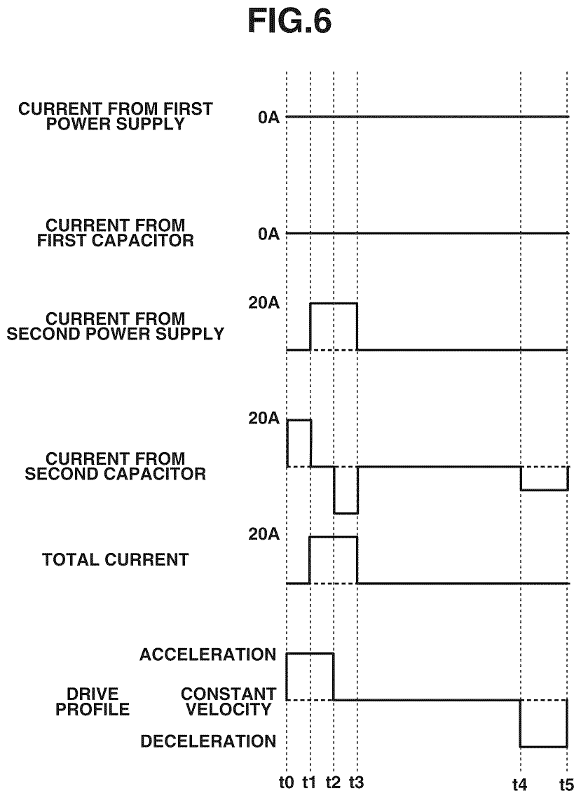

FIG. 6 illustrates an operation example of the motor drive system when one motor is driven according to the present embodiment. FIG. 6 illustrates an example of a drive profile in which only the second motor 24 for driving the substrate stage 2 is driven. In the example in FIG. 6, the reticle stage 1 is stopped in the time period from time t0 to time t5. The time period from time t0 to time t2 in FIG. 6 is an acceleration period in which the substrate stage 2 accelerates. The time period from time t2 to time t4 is a constant-velocity period in which the substrate stage 2 moves at a constant velocity. The time period from time t4 to time t5 is a deceleration period in which the substrate stage 2 decelerates. In the example in FIG. 6, since only one motor is driven, the total current value is reduced (assuming that the predetermined current value is 30 (A), the total current value of 20 (A) is lower than the predetermined current value of 30 (A)), and thus, the current value does not need to be switched.

In the acceleration period from time t0 to time t1, the second capacitor 22, which has higher responsiveness than the power supply, supplies a current of 20 (A) to its corresponding driver. As a result, the second motor 24 is driven. In the time period from time t1 to time t2, because the second capacitor 22 has already supplied all the power stored therein, the second power supply 21 supplies a current of 20 (A) needed to drive the second motor 24 to the second driver 23. As a result, the second motor 24 is driven.

In the constant-velocity period from time t2 to time t3, no power needs to be supplied to drive the substrate stage 2. However, power needs to be supplied to charge the second capacitor 22. Thus, the power supply 21 supplies power to the second capacitor 22. In the constant-velocity period from time t3 to time t4, no power is supplied from the power supply because the charging of the capacitor is already completed.

In the deceleration period from time t4 to time t5, the second motor 24 decelerates. Thus, a regenerative current returns to the second capacitor 22, and the second capacitor 22 is consequently charged.

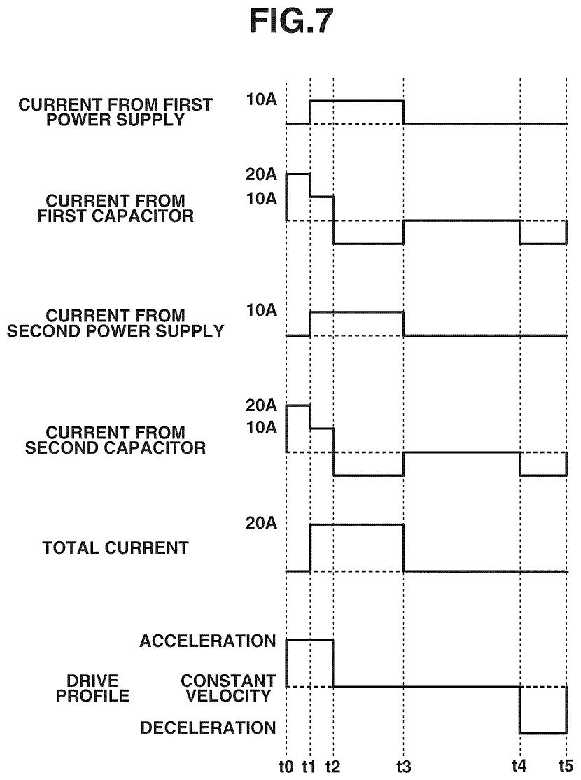

FIG. 7 is an operation example of the motor drive system when two motors simultaneously receive power according to the present embodiment. Specifically, FIG. 7 illustrates an example in which two motors simultaneously accelerate.

The time period from time t0 to time t2 in FIG. 7 is an acceleration period in which the reticle stage 1 and the substrate stage 2 accelerate. The time period from time t2 to time t4 is a constant-velocity period in which the reticle stage 1 and the substrate stage 2 move at a constant velocity. The time period from time t4 to time t5 is a deceleration period in which the reticle stage 1 and the substrate stage 2 decelerate. In the example in FIG. 7, the total current value for driving the two motors is high (assuming that the predetermined current value is 30 (A), the total current value of 40 (A) is higher than this predetermined current value of 30 (A)), and thus, at least one current value needs to be switched. In the example in FIG. 7, to reduce the peak current value (the total current value of the first power supply 11 and the second power supply 21) of the source power supply 3, the current values of the first power supply 11 and the second power supply 21 are switched from 20 (A) to 10 (A). In other words, the current values of the first power supply 11 and the second power supply 21 are each set to 10 (A). In the example in FIG. 7, the current values of both the first power supply 11 and the second power supply 21 are set to low current values. However, the current value of at least one of the first power supply 11 and the second power supply 21 may be set to a low current value, as long as the total current value becomes lower than the predetermined value.

In the acceleration period from time t0 to time t1, each of the first capacitor and the second capacitor, which have higher responsiveness than the power supplies, supplies a current of 20 (A) to its corresponding driver. As a result, the first motor and the second motor are driven. In the time period from time t1 to time t2, because the capacitors have already supplied stored power, each of the first power supply 11 and the second power supply 21 supplies a current of 10 (A) to its corresponding driver. In this case, assuming that a current of 20 (A) is needed to drive each of the first motor 14 and the second motor 24, the amount of power supplied from each power supply alone is insufficient. Therefore, in the time period from time t1 to time t2, each of the first capacitor 12 and the second capacitor 22 supplies a current of 10 (A) to compensate for the shortage of power supplied from each of the first power supply 11 and the second power supply 21. As a result, the first motor 14 and the second motor 24 are driven.

In the constant-velocity period from time t2 to time t3, no power needs to be supplied to drive the reticle stage 1 and the substrate stage 2. However, power needs to be supplied to charge the first capacitor 12 and the second capacitor 22. Thus, the first power supply 11 supplies power to the first capacitor 12, and the second power supply 21 supplies power to the second capacitor 22. In the constant-velocity period from time t3 to time t4, because the charging of the capacitors is already completed, no power is supplied from the power supplies.

In the deceleration period from time t4 to time t5, the first motor 14 and the second motor 24 decelerate. Thus, a regenerative current returns to each of the first capacitor 12 and the second capacitor 22, and the first capacitor 12 and the second capacitor 22 are consequently charged.

According to the present embodiment, a first current value, which is the current value of a power supply A (a power supply that supplies power to a motor A) when power is simultaneously supplied to the motor A and a motor B, is set to lower than a second current value, which is the current value of the power supply A when power is supplied to the motor A and no power is supplied to the motor B. That is, the first current value, which is the current value of the power supply A (the power supply that supplies power to the motor A) when the motor A and the motor B simultaneously accelerate, is set lower than the second current value, which is the current value of the power supply A when the motor A accelerates, and the motor B does not accelerate. When the power supplies supply power (when the motors accelerate), the power supplies supply a constant current value.

By performing the above-described operations, the power stored in the capacitors can be efficiently utilized, and the total current value of the first power supply 11 and the second power supply 21 (the peak value of the current output from the source power supply 3) can be reduced. This eliminates the need for a breaker having a capacity corresponding to a high current, and further eliminates the need for thick cables for supplying electricity having a high current value. In this way, an increase in the size of the motor drive system can be prevented.

The present embodiment has been described based on an example in which the current switching unit included in the individual power supply includes two types of resistors, and switches the resistor to be connected (used) to obtain a desired current value. However, the current switching unit may include three or more types of resistors having different resistance values. In this case, the current value of the individual power supply is switchable among three or more levels, and thus, the current value can be finely controlled.

The present embodiment has also been described based on an example in which the motor drive system 200 includes two motors, which are the first motor 14 and the second motor 24. However, the method for controlling the current value according to the present embodiment may also be applied to a motor drive system that includes three or more motors and power supplies corresponding to their respective motors. Different current values may be set for the power supplies. The current values of the power supplies may also be set such that the current value of the power supply corresponding to the motor that needs a larger amount of power for driving is set higher than the current value of the power supply corresponding to the other motor. For example, when the reticle stage 1 is driven at a higher velocity than the substrate stage 2, the reticle stage 1 needs a larger amount of power for driving than the substrate stage 2. In other words, the maximum current value used for driving the motor that drives the reticle stage 1 is higher than the maximum current value used for driving the motor that drives the substrate stage 2. In such a case, the current values are set such that the current value set for the first power supply 11 corresponding to the first motor 14 that drives the reticle stage 1 is set higher than the current value set for the second power supply 21 corresponding to the second motor 24 that drives the substrate stage 2. The present embodiment has been described based on an example in which the current values are set for both the first power supply 11 that supplies power to the reticle stage 1 and the second power supply 21 that supplies power to the substrate stage 2. However, a current value may also be set for either the first power supply 11 or the second power supply 21 (e.g., only for the second power supply 21).

According to the present embodiment, the current value of the individual power supply is set to a low value, and when the current is insufficient, the individual capacitor compensates for the shortage. In such a case, if a capacitor is insufficiently charged, this capacitor cannot compensate for the shortage of power, and the corresponding motor cannot perform desired driving. Thus, it is desired that the current value of the individual power supply is set to a current value at which the corresponding capacitor can be sufficiently charged by the time when this capacitor resumes supplying power. In other words, it is desired that the current value of the individual power supply is set based on the time needed to charge the corresponding capacitor and the amount of power stored in this capacitor. In addition, to sufficiently charge the individual capacitor, it is also desired that this capacitor is charged from the corresponding power supply until its maximum storage capacity is reached or until the portion of charging that cannot be covered by the regenerative current is completed. When the regenerative current from the motor and the current from the power supply simultaneously flow into the capacitor, currents in different directions simultaneously flow into the capacitor, which may cause a trouble. Thus, the power supply may be controlled such that the charging from the power supply to the capacitor is completed before the start of a deceleration period in which a regenerative current flows from the motor into the capacitor.

The present embodiment has been described based on an example of the motor drive system 200 included in the lithography apparatus 100. However, the motor drive system according to the present embodiment is not limited to this example, and is applicable to general motor drive systems in which a plurality of motors simultaneously need currents.

### Second Embodiment

A second embodiment relates to a method for manufacturing an article using the above-described motor drive system.

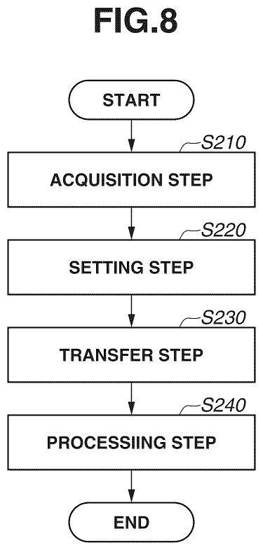

FIG. 8 is a diagram illustrating a flowchart of a method for manufacturing an article according to the present embodiment. First, in step S210, an acquisition step for acquiring information about driving of a first motor 14 for driving a reticle stage 1 and a second motor 24 for driving a substrate stage 2 is performed. Next, in step S220, a setting step for setting the value of the current supplied from a second power supply 21 to the second motor 24 (a second driver) is performed based on the information about the driving acquired in the acquisition step. Next, in step S230, a transfer step for transferring the pattern of a reticle 102 secured by the reticle stage 1 onto a substrate 104 secured by the substrate stage 2 is performed. This transfer step is performed by moving the reticle stage 1 and the substrate stage 2 relative to each other while supplying power from a first power supply 11 to the first motor 14 and supplying power from the second power supply 21, whose current value has been set in the setting step, to the second motor 24. Next, in step S240, a processing step for processing the substrate 104, onto which the pattern has been transferred in the transfer step, is performed.

The article manufactured by using this manufacturing method is, for example, a semiconductor IC element, a liquid crystal display element, a color filter, a microelectromechanical system (MEMS), and the like.

The processing step includes, for example, developing of a substrate (photosensitive material) on which a pattern has been formed, etching and resist peeling on the developed substrate, dicing, bonding, and packaging. According to the present manufacturing method, an article can be manufactured with an apparatus smaller than a conventional apparatus.

The present invention is not limited to the above embodiments, and various changes and modifications can be made without departing from the spirit and scope of the present invention.

According to the present disclosure, a compact motor drive system can be provided.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-041445, filed Mar. 14, 2025, which is hereby incorporated by reference herein in its entirety.

What is claimed is:

1. A motor drive system comprising:
a first driver configured to receive power from a first power supply and supply power to a first motor;
a second driver configured to receive power from a second power supply and supply power to a second motor; and
a setting unit configured to set a value of a current supplied from the second power supply to the second driver based on information about driving of the first motor and the second motor.

2. The motor drive system according to claim 1, further comprising a capacitor connected to the second power supply and the second driver.

3. The motor drive system according to claim 2, wherein the setting unit sets a value of a current supplied from the second power supply based on time needed to charge the capacitor and an amount of power stored in the capacitor.

4. The motor drive system according to claim 2, wherein the second driver receives power from both the second power supply and the capacitor in a case where the second motor is driven.

5. The motor drive system according to claim 2, wherein the capacitor receives power from the second power supply during a time period in which the second motor is not driven.

6. The motor drive system according to claim 1, wherein the second power supply includes:
a plurality of resistors having different resistance values; and
a switching unit configured to switch, from among the plurality of resistors, a resistor to be used based on a setting of the setting unit.

7. The motor drive system according to claim 6,
wherein the plurality of resistors include three or more resistors, and
wherein the value of the current supplied from the second power supply is switchable to three or more levels by switching of the switching unit.

8. The motor drive system according to claim 1, wherein the second power supply is a constant voltage power supply.

9. The motor drive system according to claim 1, wherein the first power supply and the second power supply receive power from a same power supply.

10. The motor drive system according to claim 1, wherein a first current value, which is a value of a current supplied from the second power supply to the second driver in a case where the first motor and the second motor simultaneously receive power, is lower than a second current value, which is a value of a current supplied from the second power supply to the second driver in a case where the first motor receives no power and the second motor receives power.

11. The motor drive system according to claim 1, wherein a first current value, which is a value of a current supplied from the second power supply to the second driver in a case where the first motor and the second motor simultaneously accelerate, is lower than a second current value, which is a value of a current supplied from the second power supply to the second driver in a case where the first motor does not accelerate and the second motor accelerates.

12. The motor drive system according to claim 1, wherein a maximum current value used for driving the first motor is higher than a maximum current value used for driving the second motor.

13. The motor drive system according to claim 1, wherein the setting unit sets a value of a current supplied from the first power supply to the first driver based on the information about driving.

14. The motor drive system according to claim 13,
wherein a maximum current value used for driving the first motor is higher than a maximum current value used for driving the second motor, and
wherein the setting unit sets a value of a current such that a value of a current supplied from the first power supply to the first driver is higher than a value of a current supplied from the second power supply to the second driver.

15. The motor drive system according to claim 1, wherein, in a case where a total current value, which is a total value of a value of a current supplied from the first power supply and a value of a current supplied from the second power supply, is higher than or equal to a threshold, the switching unit switches the value of the current supplied from the second power supply.

16. A lithography apparatus configured to transfer a pattern of a reticle onto a substrate, the lithography apparatus comprising:
a reticle stage movable while securing the reticle;
a substrate stage movable while securing the substrate;
a first motor configured to receive power from a first power supply and drive the reticle stage;
a second motor configured to receive power from a second power supply and drive the substrate stage; and
a setting unit configured to set at least one of a value of a current supplied from the first power supply or a value of a current supplied from the second power supply based on information about driving of the reticle stage and the substrate stage.

17. A method for manufacturing an article, the method comprising:
acquiring information about driving of a first motor for driving a reticle stage and a second motor for driving a substrate stage;
setting a value of a current supplied from a second power supply based on the acquired information about the driving;
transferring a pattern of a reticle secured on the reticle stage onto a substrate secured on the substrate stage by moving the reticle stage and the substrate stage relative to each other while a first power supply is supplying power to drive the first motor and the second power supply is supplying power to drive the second motor at the set value of the current; and
processing the substrate onto which the pattern has been transferred.
